(19) United States
(12) Patent Application Publication
(10) Pub. No.: US 2025/0248123 A1
(43) Pub. Date: Jul. 31, 2025

(54) DISPLAY APPARATUS

(71) Applicant: Samsung Display Co., LTD., Yongin-si (KR)

(72) Inventor: Hyuneok SHIN, Yongin-si (KR)

(21) Appl. No.: 18/915,147

(22) Filed: Oct. 14, 2024

(30) Foreign Application Priority Data
Jan. 25, 2024 (KR) 10-2024-0011726

(51) Int. Cl. H01L 27/12

(52) U.S. Cl. CPC H10D 86/60; H10D 86/451

(57) ABSTRACT

A display apparatus includes a first insulating layer, a first electrode disposed on the first insulating layer and including a lower surface in contact with an upper surface of the first insulating layer, an upper surface opposite to the lower surface, and a side surface connecting the upper surface to the lower surface, an inorganic insulating layer disposed on the first electrode, overlapping the upper surface and the side surface of the first electrode, and including an inorganic insulating material, and a second insulating layer disposed on the inorganic insulating layer, where a first portion and a second portion of an upper surface of the inorganic insulating layer face each other with a gap around a point where the upper surface of the first insulating layer and the side surface of the first electrode meet each other, and a portion of the second insulating layer is disposed in the gap.

This application claims priority to Korean Patent Application No. 10-2024-0011726, filed on Jan. 25, 2024, and all the benefits accruing therefrom under 35 U.S.C. § 119, the content of which in its entirety is herein incorporated by reference.

### BACKGROUND

### 1. Field

One or more embodiments relate to a display apparatus, and more particularly, to a display apparatus including, for example, a light-emitting diode.

### 2. Description of the Related Art

A display apparatus is an apparatus that visually displays image data. A display apparatus may include a substrate divided into a display area and a non-display area. The display area may include a plurality of subpixels. Additionally, the display area may include a thin-film transistor corresponding to each of the subpixels and a subpixel electrode electrically connected to the thin-film transistor. Additionally, the display area may include an emission layer corresponding to each of the subpixel electrodes. Additionally, opposite electrodes corresponding to the subpixels may be included in the display area. The non-display area may include various wires, a driver, a controller, etc. that transmit electrical signals to the display area. Recently, display apparatuses are widely used in various fields. Accordingly, various designs are being attempted to improve the quality of display apparatuses.

### SUMMARY

In a display device, the thickness of a gate electrode of a thin-film transistor may be increased to lower the resistance of the gate electrode. In this case, a gap may be formed in a portion of an inorganic insulating layer covering the gate electrode due to a step between an insulating layer below the gate electrode and an upper surface of the gate electrode.

In embodiments of the disclosure, an insulating layer may be additionally disposed to alleviate this step.

According to one or more embodiments, a display apparatus includes a first insulating layer, a first electrode disposed on the first insulating layer and including a lower surface in contact with an upper surface of the first insulating layer, an upper surface opposite to the lower surface, and a side surface connecting the upper surface to the lower surface, a second insulating layer disposed on the first electrode, overlapping the upper surface and the side surface of the first electrode, and including an inorganic insulating material, and a third insulating layer disposed on the second insulating layer, where a first portion and a second portion of the upper surface of the second insulating layer face each other with a gap around a point where the upper surface of the first insulating layer and the side surface of the first electrode meet each other, and a portion of the third insulating layer is disposed in the gap.

In an embodiment, the third insulating layer may include an insulating material including silicon, oxygen, and carbon, and a ratio of a number of carbon atoms to a number of silicon atoms of the third insulating layer may be about 0.6 or less.

In an embodiment, the ratio of the number of carbon atoms to the number of silicon atoms of the third insulating layer may be in a range of about 0.1 to about 0.6.

In an embodiment, a ratio of a number of oxygen atoms to the number of silicon atoms of the third insulating layer may be in a range of about 1.5 to about 2.5.

In an embodiment, a thickness of a portion of the third insulating layer overlapping the upper surface of the first electrode may be less than a thickness of a portion of the second insulating layer overlapping the upper surface of the first electrode.

In an embodiment, a thickness of a portion of the third insulating layer overlapping the upper surface of the first electrode may be less than a thickness of a portion of the third insulating layer overlapping the side surface of the first electrode.

In an embodiment, a thickness of a portion of the third insulating layer overlapping the upper surface of the first electrode may be equal to or less than about 1000 angstroms.

In an embodiment, a thickness of the first electrode may be in a range of about 3500 angstroms to about 6000 angstroms.

In an embodiment, a first inclination angle formed by the side surface of the first electrode with respect to the upper surface of the first insulating layer may be greater than a second inclination angle formed by an upper surface of a portion of the third insulating layer overlapping with the side surface of the first electrode and the upper surface of the first insulating layer.

In an embodiment, the second inclination angle may be in a range of about 50 degrees to about 60 degrees.

According to one or more embodiments, a display apparatus includes a first insulating layer, a first electrode disposed on the first insulating layer and including a lower surface in contact with an upper surface of the first insulating layer, an upper surface opposite to the lower surface, and a side surface connecting the upper surface to the lower surface, a second insulating layer disposed on the first electrode, overlapping the upper surface and the side surface of the first electrode, and including an organic insulating material, and a third insulating layer disposed on the third insulating layer and including an inorganic insulating material, where a first inclination angle of the side surface of the first electrode with respect to the upper surface of the first insulating layer is greater than a second inclination angle formed by an upper surface of a portion of the third insulating layer overlapping with the side surface of the first electrode with respect to the upper surface of the first insulating layer, and the third insulating layer is in direct contact with the upper surface and the side surface of the first electrode.

In an embodiment, the third insulating layer may include an insulating material including silicon, oxygen, and carbon, and a ratio of a number of carbon atoms to a number of silicon atoms of the third insulating layer may be in a range of about 0.6 or less.

In an embodiment, the ratio of the number of carbon atoms to the number of silicon atoms of the third insulating layer may be in a range of about 0.1 to about 0.6.

In an embodiment, a ratio of a number of oxygen atoms to the number of silicon atoms of the third insulating layer may be in a range of about 1.5 to about 2.5.

In an embodiment, a thickness of a portion of the third insulating layer overlapping the upper surface of the first electrode may be less than a thickness of a portion of the second insulating layer that overlaps the upper surface of the first electrode.

In an embodiment, a thickness of a portion of the third insulating layer overlapping the upper surface of the first electrode may be less than a thickness of a portion of the third insulating layer overlapping the side surface of the first electrode.

In an embodiment, a thickness of a portion of the third insulating layer overlapping the upper surface of the first electrode may be equal to or less than about 1000 angstroms.

In an embodiment, a thickness of the first electrode may be in a range of about 3500 angstroms to about 6000 angstroms.

In an embodiment, a maximum thickness of the third insulating layer may be less than a thickness of the first electrode.

In an embodiment, the second inclination angle may be in a range of about 50 degrees to about 60 degrees.

### BRIEF DESCRIPTION OF THE DRAWINGS

The above and other features of certain embodiments of the disclosure will be more apparent from the following description taken in conjunction with the accompanying drawings, in which:

FIG. 1 is a perspective view schematically illustrating a display apparatus according to an embodiment;

FIG. 2 is an equivalent circuit diagram schematically illustrating a subpixel of a display apparatus according to an embodiment;

FIG. 3 is a cross-sectional view of a display apparatus according to an embodiment;

FIG. 4 is an enlarged cross-sectional view of a display apparatus according to an embodiment;

FIGS. 5A, 5B, and 5C are cross-sectional views illustrating operations of a manufacturing process of a display apparatus, according to an embodiment;

FIG. 6 is a cross-sectional view of a display apparatus according to another embodiment;

FIG. 7 is an enlarged cross-sectional view of a display apparatus according to another embodiment; and

FIGS. 8A, 8B, and 8C are cross-sectional views illustrating operations of a manufacturing process of a display apparatus, according to another embodiment.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

As the disclosure allows for various changes and numerous embodiments, particular embodiments will be illustrated in the drawings and described in detail in the written description. The effects and features of the disclosure, and ways to achieve them will become apparent by referring to embodiments that will be described later in detail with reference to the drawings. However, the disclosure is not limited to the following embodiments but may be embodied in various forms.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.”.

It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

In the embodiments below, it will be understood when a portion such as a layer, an area, or an element is referred to as being “on” or “above” another portion, it can be directly on or above the other portion, or intervening portion may also be present. In contrast, when an element is referred to as being “directly on” another element, there are no intervening elements present.

Also, in the drawings, for convenience of description, sizes of elements may be exaggerated or contracted. For example, since sizes and thicknesses of elements in the drawings are arbitrarily illustrated for convenience of explanation, the following embodiments are not limited thereto.

When an embodiment is implementable in another manner, a predetermined process order may be different from a described one. For example, two processes that are consecutively described may be substantially simultaneously performed or may be performed in an opposite order to the described order.

Herein, “Or” means “and/or.” As used herein, the term “and/or” includes any and all combinations of one or more of the associated listed items. Also, “at least one of A or B” or “at least one selected from A and B” may indicate only A, only B, or both A and B. Throughout the disclosure, the expression “at least one of a, b and c” or “at least one selected from a, b and c” indicates only a, only b, only c, both a and b, both a and c, both b and c, all of a, b, and c, or variations thereof.

In the following embodiments, when layers, regions, or elements are described as being connected, other layers, this indicates a case where layers, regions, and elements are directly connected or/and a case where layers, regions, and elements are indirectly connected with other layers, regions, and elements therebetween. For example, herein, when layers, regions, or elements are described as being electrically connected, this indicates a case where layers, regions, and elements are directly electrically connected and/or a case where layers, regions, and elements are indirectly electrically connected with other layers, regions, and elements therebetween.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

An x-axis, a y-axis, and a z-axis are not limited to three axes on a rectangular coordinates system but may be construed as including these axes. For example, an-x axis, a y-axis, and a z-axis may be at right angles or may also indicate different directions from one another, which are not at right angles.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the disclosure will be described in detail with reference to the accompanying drawings, and in the description with reference to the drawings, like reference numerals refer to like elements and any repetitive detailed descriptions thereof will be omitted or simplified.

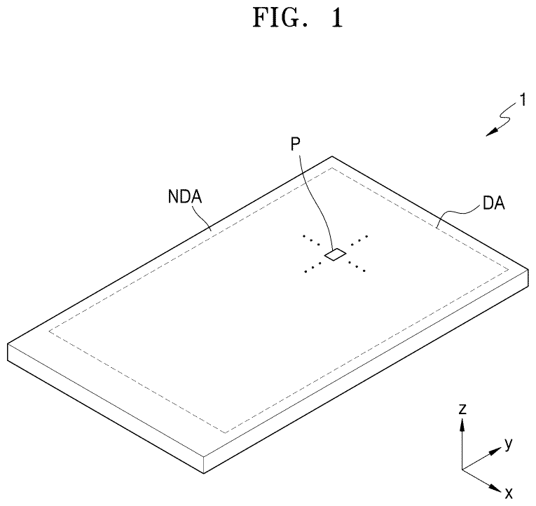

FIG. 1 is a perspective view schematically illustrating a display apparatus according to an embodiment.

Referring to FIG. 1, an embodiment of a display apparatus 1 may include a display area DA and a non-display area NDA located outside the display area DA. The display area DA may display an image through subpixels P arranged in the display area DA. The non-display area NDA is arranged outside the display area DA, is an area that does not display an image, and may entirely surround the display area DA. A driver for supplying electrical signals or power to the display area DA may be arranged in the non-display area NDA. A pad, which is an area to which an electronic element or a printed circuit board may be electrically connected, may be arranged in the non-display area NDA.

In an embodiment, as illustrated in FIG. 1, the display area DA may have a shape of a polygon (e.g., a square) in which the length of the display area DA in an x-direction is less than the length thereof in a y-direction. However, in another embodiment, the display area DA may have a shape of a polygon (e.g., a square) in which the length of the display area DA in the y-direction is less than the length thereof in the x-direction. FIG. 1 illustrates an embodiment where the display area DA is approximately a square, but the disclosure is not limited thereto. In another embodiment, for example, the display area DA may have various shapes, such as an N-gon (N is a natural number of 3 or more), a circle, or an oval. FIG. 1 illustrates an embodiment where corners of the display area DA have a shape including vertices where straight lines meet. However, in another embodiment, the display area DA may be a polygon having curved corners.

Hereinafter, for convenience of description, embodiments where the display apparatus 1 is an electronic device such as a smartphone will be described, but the display apparatus 1 of the disclosure is not limited thereto. The display apparatus 1 may be used not only in portable electronic devices, such as a mobile phone, a smartphone, a tablet personal computer (PC), a mobile communication terminal, an electronic notebook, an e-book, a portable multimedia player (PMP), a navigation device, and an ultra-mobile personal computer (UMPC), but also in various products, such as televisions, laptops, monitors, billboards, and Internet of Things (IOT) devices. In addition, the display apparatus 1 according to an embodiment may be applied to a wearable device such as a smart watch, a watch phone, a glasses-type display, and a head mounted display (HMD). Furthermore, the display apparatus 1 according an embodiment may be applied as a center information display (CID) arranged on an instrument panel of a vehicle, a center fascia, or a dashboard of a vehicle, a mirror display functioning in place of a side mirror of a vehicle, and a display arranged on the back of a front seat as an entertaining element for a rear seat of a vehicle.

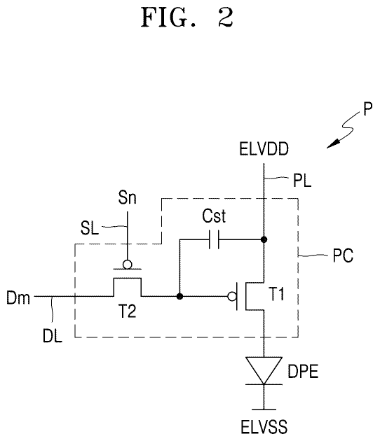

FIG. 2 is an equivalent circuit diagram schematically illustrating a subpixel of a display apparatus according to an embodiment.

The display apparatus 1 (FIG. 1) may include a subpixel P arranged in the display area DA (FIG. 1).

In an embodiment, the subpixel P may include a subpixel circuit PC and a display element DPE connected to the subpixel circuit PC. The subpixel circuit PC may include a driving thin-film transistor T1, a switching thin-film transistor T2, and a storage capacitor Cst. The subpixel P may emit light of a certain color through the display element DPE. In an embodiment, for example, the subpixel P may emit red, green, or blue light, or may emit red, green, blue, or white light through the display element DPE.

The switching thin-film transistor T2 is connected to a scan line SL and a data line DL and may transmit, to the driving thin-film transistor T1, a scan voltage input from the scan line SL or a data voltage or a data signal Dm input from the data line DL according to the scan signal Sn.

The storage capacitor Cst may be connected to the switching thin-film transistor T2 and a driving voltage line PL and may store a voltage corresponding to the difference between a voltage received from the switching thin-film transistor T2 and a first power voltage ELVDD supplied to the driving voltage line PL.

The driving thin-film transistor T1 is connected to the driving voltage line PL and the storage capacitor Cst and may control, in response to a voltage value stored in the storage capacitor Cst, a driving current flowing from the driving voltage line PL and through the display element DPE. The display element DPE may emit light with a certain luminance corresponding to a driving current. An opposite electrode (e.g., cathode) of the display element DPE may receive a second power voltage ELVSS.

In an embodiment, as shown in FIG. 2, the subpixel circuit PC may include two thin-film transistors and one storage capacitor, but the disclosure is not limited thereto, and alternatively, the subpixel circuit PC may include three or more thin-film transistors.

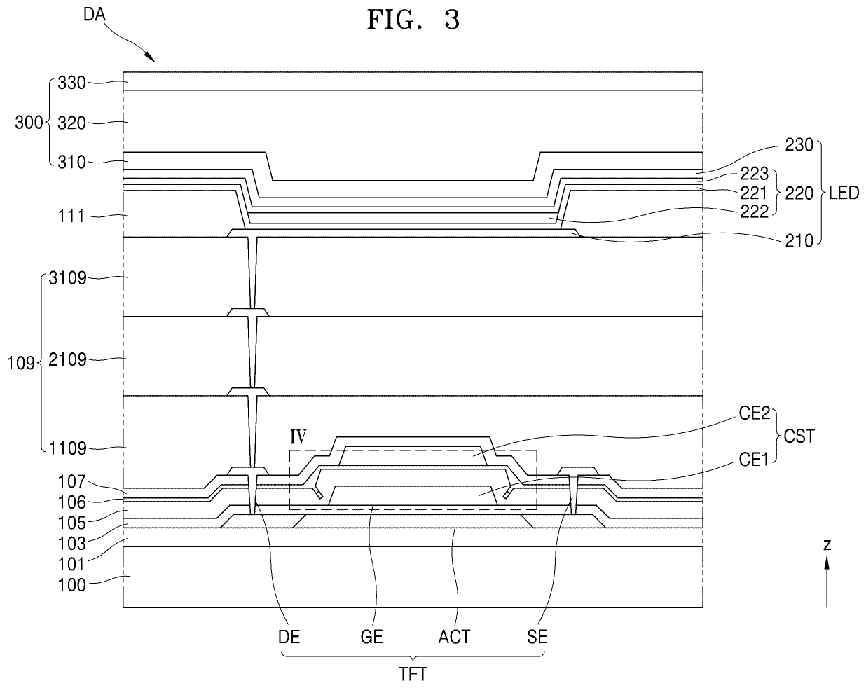

FIG. 3 is a cross-sectional view of a display apparatus according to an embodiment.

Referring to FIG. 3, in an embodiment of a display apparatus, a light-emitting diode LED may be disposed on a substrate 100 as a display element corresponding to the subpixel (P, FIG. 1). The light-emitting diode LED may be electrically connected to a thin-film transistor TFT.

A buffer layer 101 may be disposed on the substrate 100. The buffer layer 101 may planarize and protect an upper surface of the substrate 100. The buffer layer 101 may include an inorganic insulating material such as silicon oxide (SiOₓ), silicon nitride (SiNₓ), and/or silicon oxynitride (SiON) and may have a single-layer or multi-layer structure, each layer thereof including at least one selected from the above-described materials. Although not illustrated in FIG. 3, a barrier layer (not shown) may be additionally located between the substrate 100 and the buffer layer 101.

The thin-film transistor TFT may be disposed on the buffer layer 101. The thin-film transistor TFT may include an active layer ACT, a gate electrode GE, a source electrode SE, and a drain electrode DE. The thin-film transistor TFT may be connected to the light-emitting diode LED and drive the light-emitting diode LED. In some embodiments, the thin-film transistor TFT may correspond to the driving thin-film transistor (T1, FIG. 2) described with reference to FIG. 2. Although not illustrated in FIG. 3, a switching thin-film transistor (T2, FIG. 2) may also be disposed on the buffer layer 101.

The active layer ACT may be disposed on the buffer layer 101 and may include a drain region overlapping with the drain electrode DE, a source region overlapping with the source electrode SE, and a channel region disposed between the drain region and the source region. The drain region and the source region may be regions doped with impurities. Impurities doped in the drain region and the source region may be different from each other.

The first insulating layer 103 may be disposed on the active layer ACT. The first insulating layer 103 may include an inorganic material including oxide or nitride. In an embodiment, for example, the first insulating layer 103 may include at least one selected from silicon oxide (SiOₓ), silicon nitride (SiNₓ), silicon oxynitride (SiON), aluminum oxide (Al₂O₃), titanium oxide (TiO₂), tantalum oxide (Ta₂O₅), hafnium oxide (HfO₂), and zinc oxide (ZnO₂), etc. and may have a single-layer or multi-layer structure, each layer thereof including at least one selected from the above-described materials.

The gate electrode GE may be disposed on the first insulating layer 103. The gate electrode GE may at least partially overlap the active layer ACT. In an embodiment, for example, the gate electrode GE may overlap a channel region of the active layer ACT. The gate electrode GE may include aluminum (AI), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu) and may have a single-layer or multi-layer structure, each layer thereof including at least one selected from the materials described above.

The second insulating layer 105 may be disposed to cover the gate electrode GE. The second insulating layer 105 may include an inorganic material including oxide or nitride. In an embodiment, for example, the second insulating layer 105 may include at least one selected from silicon oxide (SiOₓ), silicon nitride (SiNₓ), silicon oxynitride (SiON), aluminum oxide (Al₂O₃), titanium oxide (TiO₂), tantalum oxide (Ta₂O₅), hafnium oxide (HfO₂), and zinc oxide (ZnO₂), etc. and may have a single-layer or multi-layer structure, each layer thereof including at least one selected from the above-described materials.

The second insulating layer 105 may include a gap in an area around or close to a point where a side surface of the gate electrode GE and an upper surface of the first insulating layer 103 meet each other. This will be described in greater detail below.

A third insulating layer 106 may be disposed on the second insulating layer 105. The third insulating layer 106 may cover the second insulating layer 105, and a portion of the third insulating layer 106 may be disposed within the gap of the second insulating layer 105. The third insulating layer 106 may include an organic insulating material. In an embodiment, for example, the third insulating layer 106 may include hexamethyldisiloxane.

The storage capacitor Cst may include a first electrode layer CE1 and a second electrode layer CE2. In an embodiment, the storage capacitor Cst may be arranged to overlap the thin-film transistor TFT. In such an embodiment, the gate electrode GE may function not only as a gate electrode of the thin-film transistor TFT but also as the first electrode layer CE1 of the storage capacitor Cst. That is, the gate electrode GE of the thin-film transistor TFT and the first electrode layer CE1 of the storage capacitor Cst may be formed as a single body. The second electrode layer CE2 may overlap the first electrode layer CE1 or the gate electrode GE. In another embodiment, the storage capacitor Cst does not overlap the thin-film transistor TFT and may be in a separate location. In such an embodiment, the first electrode layer CE1 of the storage capacitor Cst and the gate electrode GE of the thin-film transistor TFT may be formed as separate elements.

The fourth insulating layer 107 may be disposed to cover the second electrode layer CE2. The fourth insulating layer 107 may include an inorganic material including oxide or nitride. In an embodiment, for example, the fourth insulating layer 107 may include at least one selected from silicon oxide (SiOₓ), silicon nitride (SiNₓ), silicon oxynitride (SiON), aluminum oxide (Al₂O₃), titanium oxide (TiO₂), tantalum oxide (Ta₂O₅), hafnium oxide (HfO₂), and zinc oxide (ZnO₂), etc. and may have a single-layer or multi-layer structure, each layer thereof including at least one selected from the above-described materials.

The first insulating layer 103, the second insulating layer 105, the third insulating layer 106, and the fourth insulating layer 107 may include contact holes overlapping the source region and the drain region of the active layer ACT. In an embodiment, for example, the first insulating layer 103, the second insulating layer 105, the third insulating layer 106, and the fourth insulating layer 107 may each be provided with an opening that overlaps the source region and the drain region and is defined through each layer, and the openings may overlap each other and be connected to each other to form a contact hole.

The source electrode SE and the drain electrode DE may be disposed on the fourth insulating layer 107. The source electrode SE may be disposed to overlap the source region of the active layer ACT, and the drain electrode DE may be disposed to overlap the drain region of the active layer ACT. The source electrode SE and the drain electrode DE may be each connected to the active layer ACT through the contact hole defined or formed in the first insulating layer 103, the second insulating layer 105, the third insulating layer 106, and the fourth insulating layer 107.

A via layer 109 may be disposed on the source electrode SE and the drain electrode DE. The via layer 109 may include first to third via layers 1109, 2109, and 3109.

The first via layer 1109 may be disposed to cover the source electrode SE and the drain electrode DE. The first via layer 1109 may be provided with an opening that overlaps the drain electrode DE. The first via layer 1109 may include general-purpose polymers such as benzocyclobutene, polyimide, hexamethyldisiloxane, polymethylmethacrylate or polystyrene, a polymer derivative having a phenol group, acrylic polymer, imide polymer, aryl ether polymer, amide polymer, fluorine polymer, p-xylene polymer, or vinyl alcohol polymer, etc. and may have a single-layer structure or a multi-layer structure, each layer thereof including at least one selected from the above-described materials.

A connecting metal may be disposed on the first via layer 1109. A portion of the connecting metal may be disposed within the opening of the first via layer 1109. The connecting metal may be connected to the drain electrode DE through the opening of the first via layer 1109. The connecting metal may include aluminum (Al), copper (Cu), and/or titanium (Ti) and may have a single-layer structure or a multi-layer structure, each layer thereof including at least one selected from the above-described materials.

The second via layer 2109 may be disposed to cover the first via layer 1109. The second via layer 2109 may include an opening that overlaps the connecting metal disposed on the first via layer 1109. The second via layer 2109 may include general-purpose polymers such as benzocyclobutene, polyimide, hexamethyldisiloxane, polymethylmethacrylate or polystyrene, a polymer derivative having a phenol group, acrylic polymer, imide polymer, aryl ether polymer, amide polymer, fluorine polymer, p-xylene polymer, or vinyl alcohol polymer, etc. and may have a single-layer structure or a multi-layer structure, each layer thereof including at least one selected from the above-described materials.

A connecting metal may be disposed on the second via layer 2109. A portion of the connecting metal may be disposed within the opening of the second via layer 2109. The connecting metal may be connected to the connecting metal disposed on the first via layer 1109 through the opening of the second via layer 2109. The connecting metal may include aluminum (Al), copper (Cu), and/or titanium (Ti) and may have a single-layer structure or a multi-layer structure, each layer thereof including at least one selected from the above-described materials.

The third via layer 3109 may be arranged to cover the second via layer 2109. The third via layer 3109 may be provided with an opening that overlaps the connecting metal disposed on the second via layer 2109. The third via layer 3109 may include general-purpose polymers such as benzocyclobutene, polyimide, hexamethyldisiloxane, polymethylmethacrylate or polystyrene, a polymer derivative having a phenol group, acrylic polymer, imide polymer, aryl ether polymer, amide polymer, fluorine polymer, p-xylene polymer, or vinyl alcohol polymer, etc. and may have a single-layer structure or a multi-layer structure, each layer thereof including at least one selected from the above-described materials.

FIG. 3 illustrates an embodiment including two connecting metals and three via layers (e.g., the first to third via layers 1109, 2109, and 3109), but the disclosure is not limited thereto. In another embodiment, the via layer may be a single layer and the connecting metal may be omitted. Alternatively, the via layer may include two layers and one connecting metal may be included.

A subpixel electrode 210 may be disposed on the third via layer 3109. The subpixel electrode 210 may be connected to the connecting metal through the opening formed in the third via layer 3109. Accordingly, the subpixel electrode 210 may be electrically connected to the thin-film transistor TFT through the connecting metal and the drain electrode DE and receive voltage.

The subpixel electrode 210 may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). In another embodiment, the subpixel electrode 210 may include a reflective layer including silver (Ag), magnesium (Mg), aluminum (Al), platinum (Pt), palladium (Pd), gold (Au), nickel (Ni), neodymium (Nd), iridium (Ir), chromium (Cr), or a compound thereof. The composition and material of the subpixel electrode 210 are not limited thereto and may be variously modified.

A bank layer 111 may be disposed on the third via layer 3109. The bank layer 111 may cover an edge (or an edge area) of the subpixel electrode 210. In other words, the bank layer 111 may be opened to expose a central portion of the subpixel electrode 210. The size and shape of a light-emitting area of the light-emitting diode LED may be determined by the opening of the bank layer 111.

An intermediate layer 220 may be disposed on the subpixel electrode 210. The intermediate layer 220 may include a first common layer 221 and a second common layer 223 disposed on the bank layer 111, and an emission layer 222 disposed within the opening of the bank layer 111. In some embodiments, a first common layer 221 may be disposed on the bank layer 111, and the emission layer 222 may be disposed within the opening of the bank layer 111 on the first common layer 221, and the second common layer 223 may be disposed on the first common layer 221 to cover the emission layer 222. In other words, the emission layer 222 may be disposed within the opening of the bank layer 111 and between the first and second common layers 221 and 223.

The emission layer 222 may include an organic emission layer including a low molecule or polymer material. The first common layer 221 may include an electron transport layer (ETL) and/or an electron injection layer (EIL). The second common layer 223 may include a hole transport layer (HTL) and/or a hole injection layer (HIL). In some embodiments, the first common layer 221 or the second common layer 223 may be omitted. In some embodiments, the position of the first common layer 221 may be changed with the position of the second common layer 223.

An opposite electrode 230 may be disposed on the intermediate layer 220. In an embodiment, for example, an opposite electrode may be disposed on the second common layer 223. The opposite electrode 230 may be arranged to entirely cover the intermediate layer 220. The opposite electrode 230 may include a conductive material having a low work function. In an embodiment, for example, the opposite electrode 230 may include a (semi) transparent layer including Ag, Mg, Al, Pt, Pd, Au, Ni, Nd, Ir, Cr, Li, Ca, or an alloy thereof. Alternatively, the opposite electrode 230 may further include a layer such as ITO, IZO, ZnO, or In₂O₃ on the (semi) transparent layer including the above-described material.

An encapsulation layer 300 may be disposed on the opposite electrode 230. The encapsulation layer 300 may include at least one inorganic layer and at least one organic layer. In an embodiment, the encapsulation layer 300 may include a first inorganic encapsulation layer 310 and a second inorganic encapsulation 330 and an organic encapsulation layer 320 therebetween. The first and second inorganic encapsulation layers 310 and 330 may include at least one inorganic insulating material such as silicon oxide (SiOₓ), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂). The organic encapsulation layer 320 may include a polymer-based material. The polymer-based material may include at least one selected from silicone-based resin, acrylic resin, epoxy-based resin, polyimide, and polyethylene.

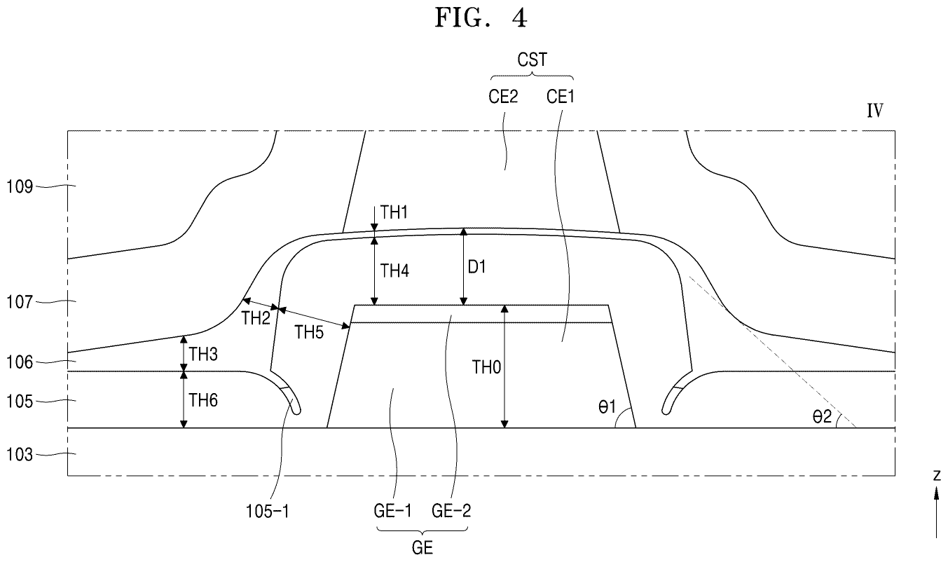

FIG. 4 is an enlarged cross-sectional view of a display apparatus according to an embodiment. Particularly, FIG. 4 is an enlarged cross-sectional view of region IV of FIG. 3.

Referring to FIG. 4, in an embodiment of a display apparatus, the gate electrode GE (or the first electrode layer CE1) may be disposed on the first insulating layer 103. The second insulating layer 105, the third insulating layer 106, and the fourth insulating layer 107 may be sequentially disposed on the gate electrode GE.

The gate electrode GE1 may include a first layer GE-1 and a second layer GE-2. The first layer GE-1 may be disposed on the upper surface of the first insulating layer 103. The first layer GE-1 and the second layer GE-2 may include different materials, respectively. In an embodiment, for example, the first layer GE-1 may include aluminum (Al), and the second layer GE-2 may include titanium (Ti).

The gate electrode GE may include a lower surface in contact with the first insulating layer 103, an upper surface located opposite to the lower surface, and a side surface connecting the lower surface to the upper surface. In an embodiment, the lower surface of the gate electrode GE may be a lower surface of the first layer GE-1. In an embodiment, the upper surface of the gate electrode GE may be an upper surface of the second layer GE-2. In an embodiment, the gate electrode GE may have a tapered shape in a cross-section. In other words, the side surface of the gate electrode GE may be inclined with respect to the upper surface of the first insulating layer 103. In such an embodiment, an angle formed by the side surface of the gate electrode GE and the upper surface of the first insulating layer 103 may be defined as a first angle θ1. In an embodiment, the first angle θ1 may be in a range of about 60 degrees to about 70 degrees. In an embodiment, the gate electrode GE may have a certain thickness. A thickness of the gate electrode GE may be the sum of the thickness of the first layer GE-1 and the thickness of the second layer GE-2. The thickness of the gate electrode GE may be defined as a zeroth thickness TH0. In an embodiment, the thickness of the gate electrode GE, or the zeroth thickness TH0, may be in a range of about 3500 angstroms (Å) to about 6000 Å. In other words, the zeroth thickness TH0 may be in a range of about 0.35 micrometers (μm) to about 0.6 μm.

The second insulating layer 105 may cover the gate electrode GE. A portion of the second insulating layer 105 may overlap the upper surface of the gate electrode GE. A thickness of the portion of the second insulating layer 105 that overlaps the upper surface of the gate electrode GE may be defined as a fourth thickness TH4. Another portion of the second insulating layer 105 may overlap the side surface of the gate electrode GE. A thickness of the portion of the second insulating layer 105 that overlaps the side surface of the gate electrode GE may be defined as a fifth thickness TH5. Another portion of the second insulating layer 105 may overlap the upper surface of the first insulating layer 103. A thickness of the portion of the second insulating layer 105 that overlaps the upper surface of the first insulating layer 103 may be defined as a sixth thickness TH6. In an embodiment, the fourth thickness TH4, the fifth thickness TH5, and the sixth thickness TH6 may be substantially equal to each other. In an embodiment, the fourth thickness TH4, the fifth thickness TH5, and the sixth thickness TH6 may be less than the zero thickness TH0.

The second insulating layer 105 may include a gap 105-1 defined in an area around or close to a point where the upper surface of the first insulating layer 103 and the side surface of the gate electrode GE meet each other. In an embodiment, a plurality of gaps 105-1 may be located in areas around or close to opposing sides of the gate electrode GE, respectively. A portion of the second insulating layer 105 overlapping the upper surface of the first insulating layer 103 (e.g., a first portion) and another portion of the second insulating layer 105 overlapping the side surface of the gate electrode GE (e.g., a second portion) may face each other with the gap 105-1 therebetween. The gap 105-1 of the second insulating layer 105 may be formed by a step between the upper surface of the first insulating layer 103 and the upper surface of the gate electrode GE in a process of covering the gate electrode GE and the first insulating layer 103 with the second insulating layer 105. In an embodiment, for example, as the zeroth thickness TH0 of the gate electrode GE increases, the probability of forming the gap 105-1 and/or the size of the gap 105-1 may increase.

The third insulating layer 106 may be disposed on the second insulating layer 105. The third insulating layer 106 may cover the second insulating layer 105. A portion of the third insulating layer 106 may overlap the upper surface of the gate electrode GE. A thickness of the portion of the third insulating layer 106 that overlaps the upper surface of the gate electrode GE may be defined as a first thickness TH1. The portion of the third insulating layer 106 having the first thickness TH1 may overlap the portion of the second insulating layer 105 having the fourth thickness TH4. Another portion of the third insulating layer 106 may overlap the side surface of the gate electrode GE. A thickness of the portion of the third insulating layer 106 that overlaps the side surface of the gate electrode GE may be defined as a second thickness TH2. The portion of the third insulating layer 106 having the second thickness TH2 may overlap the portion of the second insulating layer 105 having the fifth thickness TH5. Another portion of the third insulating layer 106 may overlap the upper surface of the first insulating layer 103. A thickness of the portion of the third insulating layer 106 that overlaps the upper surface of the first insulating layer 103 may be defined as a third thickness TH3. The portion of the third insulating layer 106 having the third thickness TH3 may overlap the portion of the second insulating layer 105 having the sixth thickness TH6.

In an embodiment, the first thickness TH1 may be less than the fourth thickness TH4. In an embodiment, the second thickness TH2 may be less than the fifth thickness TH5. In an embodiment, the third thickness TH3 may be less than the fifth thickness TH5. In an embodiment, the first thickness TH1 may be less than the second thickness

TH2 and the third thickness TH3. In an embodiment, the second thickness TH2 may be substantially the same as the third thickness TH3. In an embodiment, the second thickness TH2 may be less than the third thickness TH3. In an embodiment, the first thickness TH1 may be about 1000 Å or less. In other words, the first thickness TH1 may be about 0.1 micrometer or less. As described above, the thickness of a portion of the third insulating layer 106 may vary depending on the location thereof.

An upper surface of a portion of the third insulating layer 106 that overlaps the side surface of the gate electrode GE may be inclined with respect to the upper surface of the first insulating layer 103. In an embodiment, for example, if a tangent line is drawn to touch the upper surface of the portion of the third insulating layer 106 overlapping the side surface of the gate electrode GE, the tangent line may form a second angle θ2 with the upper surface of the first insulating layer 103. The second angle θ2 may indicate how gentle an inclination of the portion of the third insulating layer 106 overlapping the side surface of the gate electrode GE is. In an embodiment, the second angle θ2 may be less than the first angle θ1. In an embodiment, the second angle θ2 may be in a range of about 50 degrees to about 60 degrees. In an embodiment, the second angle θ2 may be about 50 degrees or less. As described above, the third insulating layer 106 may alleviate the inclination of the second insulating layer 105 formed by the gate electrode GE having the zero thickness TH0 and the inclination of the side surface of the gate electrode GE.

In an area around or close to a point where the upper surface of the first insulating layer 103 and the side surface of the gate electrode GE meet each other, a portion of the third insulating layer 106 may be located within the gap 105-1 of the second insulating layer 105. In an embodiment, as illustrated in FIG. 4, the third insulating layer 106 may fill a portion of the gap 105-1 of the second insulating layer 105. In another embodiment, unlike illustrated in FIG. 4, the third insulating layer 106 may completely fill the gap 105-1 of the second insulating layer 105.

The third insulating layer 106 may include an organic insulating material. In an embodiment, for example, the third insulating layer 106 may include an organic insulating material with high fluidity or high reflow characteristics. Accordingly, a portion of the third insulating layer 106 may flow into the gap 105-1 and be disposed within the gap 105-1. Additionally, a portion of the third insulating layer 106 may flow, so that the second angle θ2 may be less than the first angle θ1. In other words, the high fluidity of the third insulating layer 106 may allow the inclination of the portion of the third insulating layer 106 overlapping the side surface of the gate electrode GE gentle, i.e., to be less than that of the side surface of the gate electrode GE.

In an embodiment, the third insulating layer 106 may include hexamethyldisiloxane (SiOₓC_{y}). In an embodiment, a ratio of the number of carbon atoms to the number of silicon atoms in the third insulating layer 106 may be about 0.6 or less. In an embodiment, the ratio of the number of carbon atoms to the number of silicon atoms in the third insulating layer 106 may be in a range of about 0.1 to about 0.6. As the ratio of the number of carbon atoms to the number of silicon atoms in the third insulating layer 106 decreases, the transmittance of the third insulating layer 106 may increase. In an embodiment, a ratio of the number of oxygen atoms to the number of silicon atoms in the third insulating layer 106 may be in a range of about 1.5 to about 2.5. Through the atomic composition of the third insulating layer 106 as described above, the atomic composition of hexamethyldisiloxane included in the third insulating layer 106 may be substantially close to silicon oxide (SiOₓ) and the fluidity of the third insulating layer 106 may be maximized.

The second electrode layer CE2 may be disposed on the third insulating layer 106. The first electrode layer CE1 (or gate electrode GE) and the second electrode layer CE2 may form a storage capacitor CST. Accordingly, the first electrode layer CE1 and the second electrode layer CE2 may overlap each other. By reducing a distance between the first electrode layer CE1 and the second electrode layer CE2, for example, a first distance D1, the capacity of the storage capacitor Cst may be increased. In an embodiment, the first distance D1 may be a sum of the first thickness TH1 and the fourth thickness TH4. Accordingly, as the first thickness TH1 and/or the fourth thickness TH4 are reduced, the first distance D1 may be reduced and the capacity of the storage capacitor CST may be increased.

The fourth insulating layer 107 and the via layer 109 may be sequentially disposed on the second electrode layer CE2.

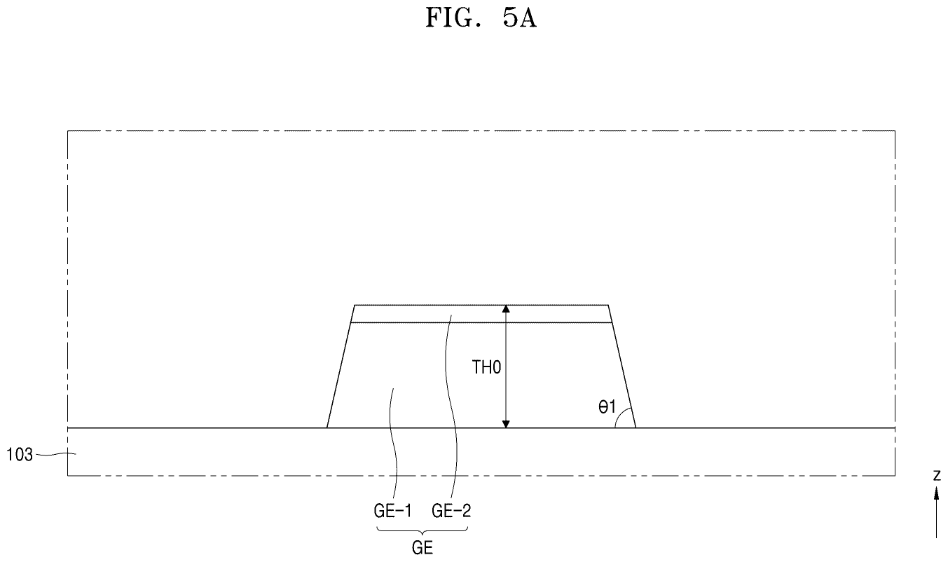

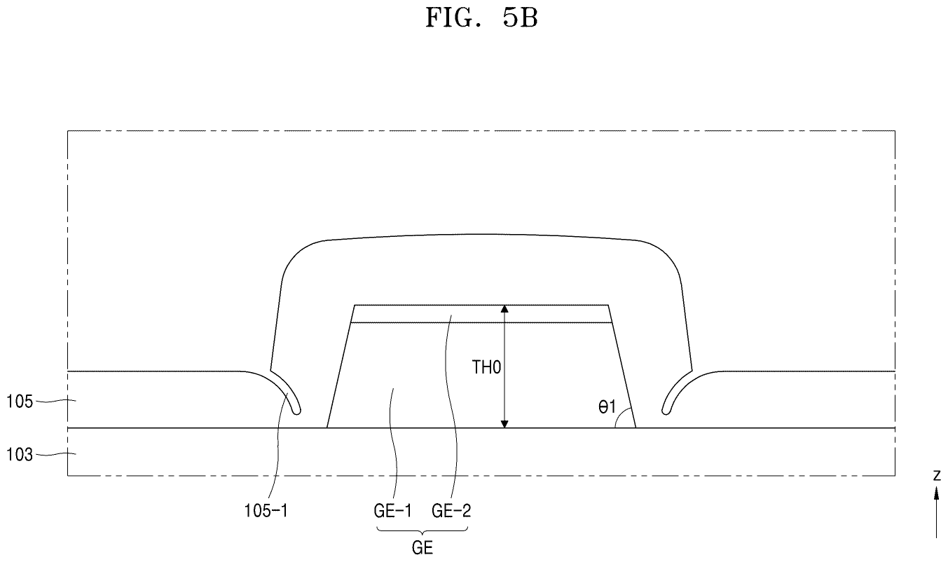

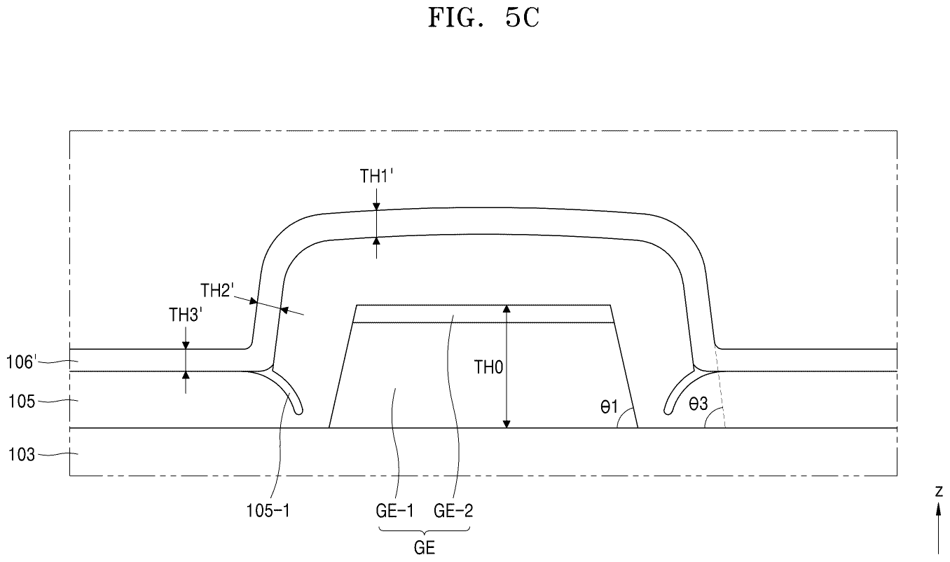

FIGS. 5A, 5B, and 5C are cross-sectional views illustrating operations of a manufacturing process of a display apparatus, according to an embodiment. Particularly, FIGS. 5A, 5B, and 5C may be cross-sectional views illustrating operations in the manufacturing process of the embodiment illustrated in FIG. 4.

Referring to FIG. 5A, the gate electrode GE may be provided or formed on the first insulating layer 103. The gate electrode GE may include the first layer GE-1 and the second layer GE-2, and may have the zero thickness TH0. The gate electrode GE may include a lower surface in contact with the first insulating layer 103, an upper surface opposite to the lower surface, and a side surface connecting the lower surface to the upper surface. The side surface of the gate electrode GE may form the first angle θ1 with the upper surface of the first insulating layer 103.

Referring to FIG. 5B, the second insulating layer 105 may be provided or formed on the first insulating layer 103 and the gate electrode GE. The second insulating layer 105 may cover the gate electrode GE. The gap 105-1 may be formed in an area around or close to a point where the upper surface of the first insulating layer 103 and the side surface of the gate electrode GE meet each other. The gap 105-1 may be formed by a step between the upper surface of the first insulating layer 103 and the upper surface of the gate electrode GE. In other words, the gap 105-1 may be formed by the zero thickness TH0 and the first angle θ1. In another embodiment, if the zeroth thickness TH0 and/or the first angle θ1 are reduced, the gap 105-1 may not be formed.

Referring to FIG. 5C, an organic layer 106′ may be provided or formed on the second insulating layer 105. The organic layer 106′ may cover the second insulating layer 105. A portion of the organic layer 106′ may overlap the upper surface of the gate electrode GE. A thickness of the portion of the organic layer 106′ overlapping the upper surface of the gate electrode GE may be defined as a first initial thickness TH1′. Another portion of the organic layer 106′ may overlap the side surface of the gate electrode GE. A thickness of the portion of the organic layer 106′ overlapping the side surface of the gate electrode GE may be defined as a second initial thickness TH2′. Another portion of the organic layer 106′ may overlap the upper surface of the first insulating layer 103. A thickness of the portion of the organic layer 106′ overlapping the upper surface of the first insulating layer 103 may be defined as a third initial thickness TH3′. In an embodiment, the first initial thickness TH1′, the second initial thickness TH2′, and the third initial thickness TH3′ may be substantially the same as each other. In an embodiment, the first initial thickness TH1′, the second initial thickness TH2′, and the third initial thickness TH3′ may be less than the zeroth thickness TH0.

In an embodiment, the organic layer 106′ may be formed through chemical vapor deposition (CVD). The thickness of the organic layer 106′ may be substantially constant throughout at this stage in the process. Therefore, at an initial stage of the process, the inclination angle of the portion of the organic layer 106′ overlapping the side surface of the gate electrode GE may be substantially equal to the inclination angle of the side surface of the gate electrode GE and an inclination angle of the second insulating layer 105 overlapping the side surface of the gate electrode GE. In an embodiment, for example, the upper surface of a portion of the organic layer 106′ overlapping the side surface of the gate electrode GE may form a third angle θ3 with the upper surface of the first insulating layer 103. In an embodiment, the first θ01 may be substantially the same as the third angle θ3.

In an embodiment, the organic layer 106′ may include a same material as the third insulating layer 106 (FIG. 4). Accordingly, the organic layer 106′ may have high fluidity.

Referring to FIG. 5C, in the initial stage, the first initial thickness TH1′, the second initial thickness TH2′, and the third initial thickness TH3′ of the organic layer 106′ are substantially the same as each other, and the organic layer 106′ is not located within the gap 105-1. Additionally, in FIG. 5C, the third θ3 is shown to be substantially equal to the first angle θ1. However, the organic layer 106′ may flow, and the shape of the organic layer 106′ may change after a certain period of time, for example, under the influence of gravity. In an embodiment, a portion of the organic layer 106′ overlapping the upper surface of the gate electrode GE may flow to an area overlapping the side surface of the gate electrode GE. Accordingly, the first initial thickness TH1′ may become less than the second initial thickness TH2′ and the third initial thickness TH3′. In an embodiment, a portion of the organic layer 106′ may flow into the gap 105-1 and be disposed within the gap 105-1. In this case, the portion of the organic layer 106′ may fill a portion of the gap 105-1 or the entire gap 105-1. In an embodiment, a portion of the organic layer 106′ may flow and the thickness of the portion overlapping the side surface of the gate electrode GE (e.g., the second thickness TH2′) and the thickness of the portion overlapping with the upper surface of the first insulating layer 103 (e.g., the third thickness TH3′) may increase. Accordingly, the third angle θ3 may decrease. The organic layer 106′ after undergoing the above flow process may be substantially the same as the third insulating layer 106 (FIG. 4) illustrated in FIG. 4.

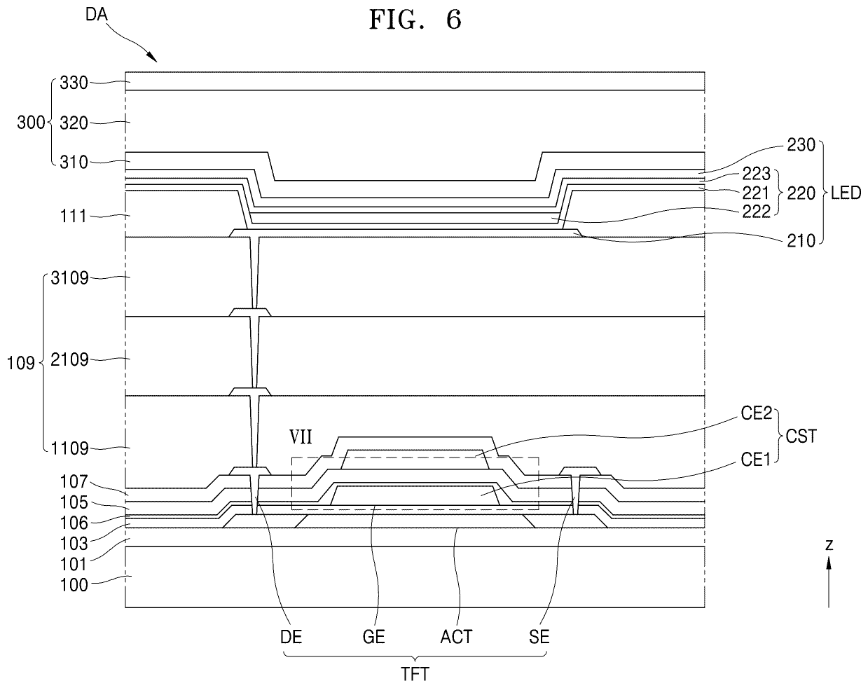

FIG. 6 is a cross-sectional view of a display apparatus according to another embodiment.

The display apparatus shown in FIG. 6 is substantially the same as the display apparatus shown in FIG. 3 except for the second insulating layer 105 and the third insulating layer 106. The same or like elements shown in FIG. 6 have been labeled with the same reference characters as used above to describe the embodiment of the display apparatus shown in FIG. 3, and any repetitive detailed description thereof will hereinafter be omitted or simplified.

Referring to FIG. 6, in an embodiment of the display apparatus, the third insulating layer 106 may be disposed on the gate electrode GE (or the first electrode layer CE1) and the first insulating layer 103. In an embodiment, for example, the third insulating layer 106 may cover the gate electrode GE. The second insulating layer 105 may be disposed on the third insulating layer 106. The second insulating layer 105 may cover the third insulating layer 106. An inclination of an upper surface of the portion of the third insulating layer 106 that overlaps the side surface of the gate electrode GE may be different from the inclination of the side surface of the gate electrode GE. An inclination of an upper surface of the portion of the second insulating layer 105 that overlaps the side surface of the gate electrode GE may be different from the inclination of the side surface of the gate electrode GE.

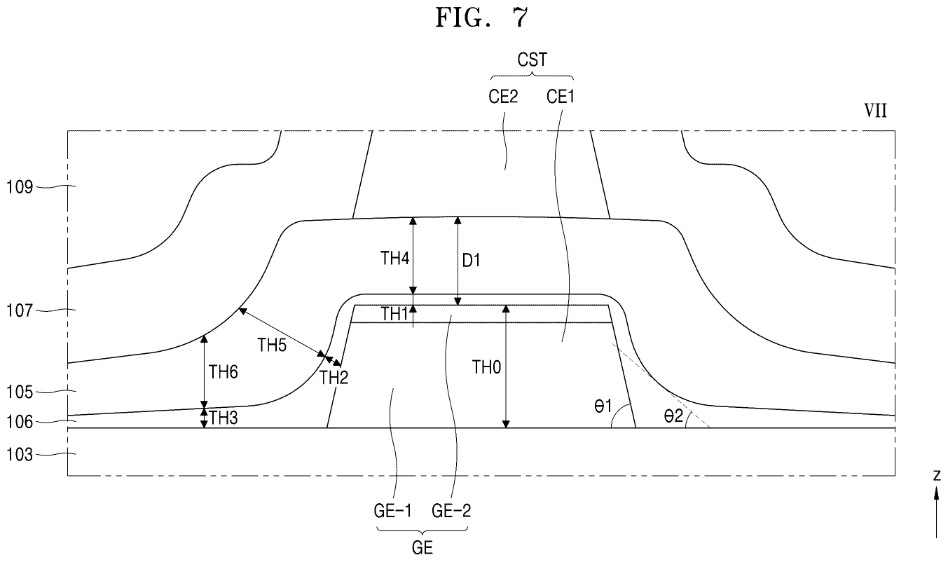

FIG. 7 is an enlarged cross-sectional view of a display apparatus according to another embodiment. Particularly, FIG. 7 is an enlarged cross-sectional view of region VII of FIG. 6.

Referring to FIG. 7, in an embodiment of a display apparatus, the third insulating layer 106 may be disposed on the gate electrode GE and the first insulating layer 103. The third insulating layer 106 may directly contact the gate electrode GE and the first insulating layer 103. In an embodiment, for example, the third insulating layer 106 may directly contact the upper surface and the side surface of the gate electrode GE and the upper surface of the first insulating layer 103. The third insulating layer 106 may also be disposed in an area around or close to a point where the upper surface of the first insulating layer 103 and the side surface of the gate electrode GE meet.

A portion of the third insulating layer 106 may overlap the side surface of the gate electrode GE. A tangent line drawn on the upper surface of the portion of the third insulating layer 106 that overlaps the side surface of the gate electrode GE may form a second inclination angle with the upper surface of the first insulating layer 103. The side surface of the gate electrode GE may form the first θ01 with the upper surface of the first insulating layer 103. The relationship between the first angle θ1 and the second angle θ2 is substantially the same as that described above. Accordingly, the third insulating layer 106 may alleviate an inclination formed by the side surface of the gate electrode GE.

The second insulating layer 105 may be disposed on the third insulating layer 106 and may cover the third insulating layer 106. The inclination angle of the portion of the second insulating layer 105 overlapping the side surface of the gate electrode GE may be substantially the same as the inclination angle of the portion of the third insulating layer 106 overlapping the side surface of the gate electrode GE (e.g., the second angle θ2). Since a portion of the second insulating layer 105 may be disposed on an inclination surface alleviated by the third insulating layer 106, the second insulating layer 105 illustrated in FIG. 6 may not include the gap 105-1 (FIG. 4) unlike the second insulating layer 105 illustrated in FIG. 4.

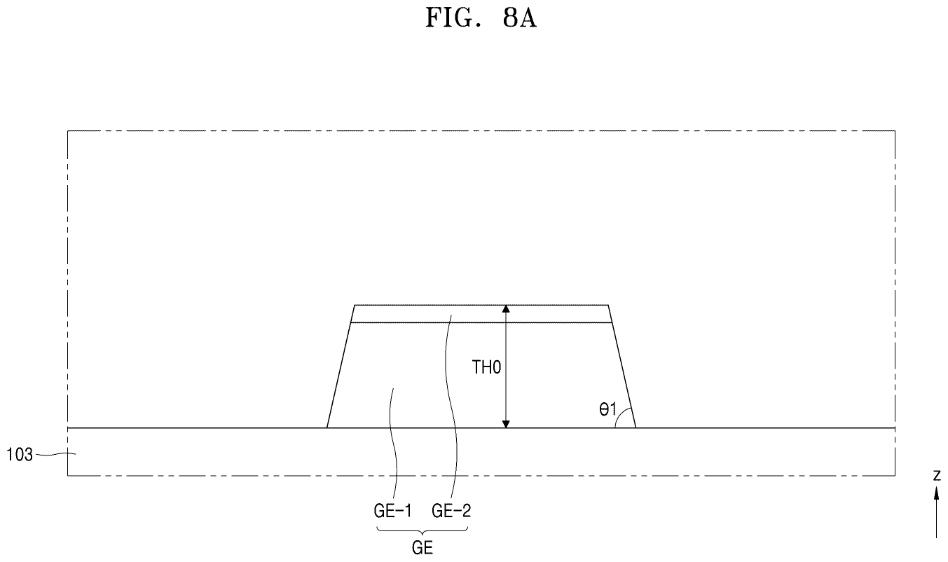

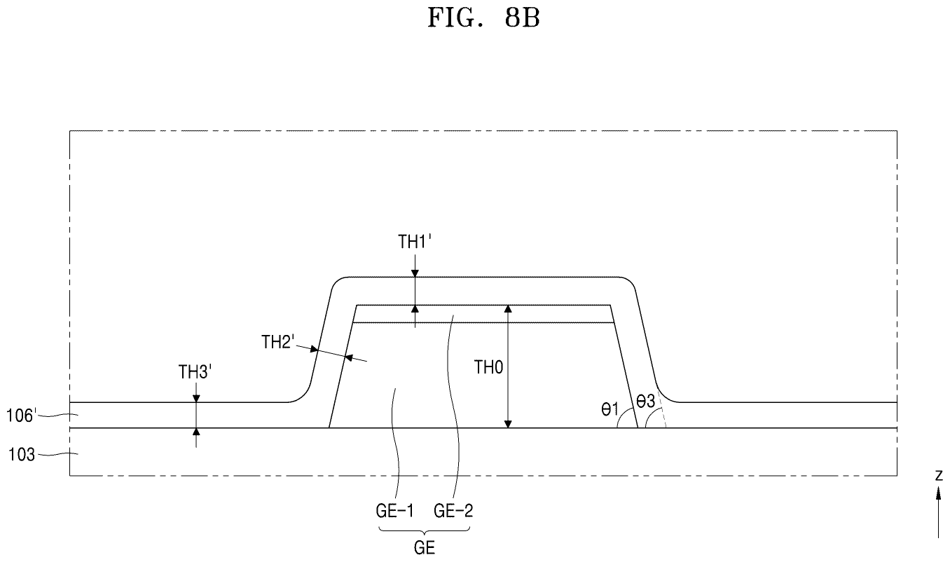

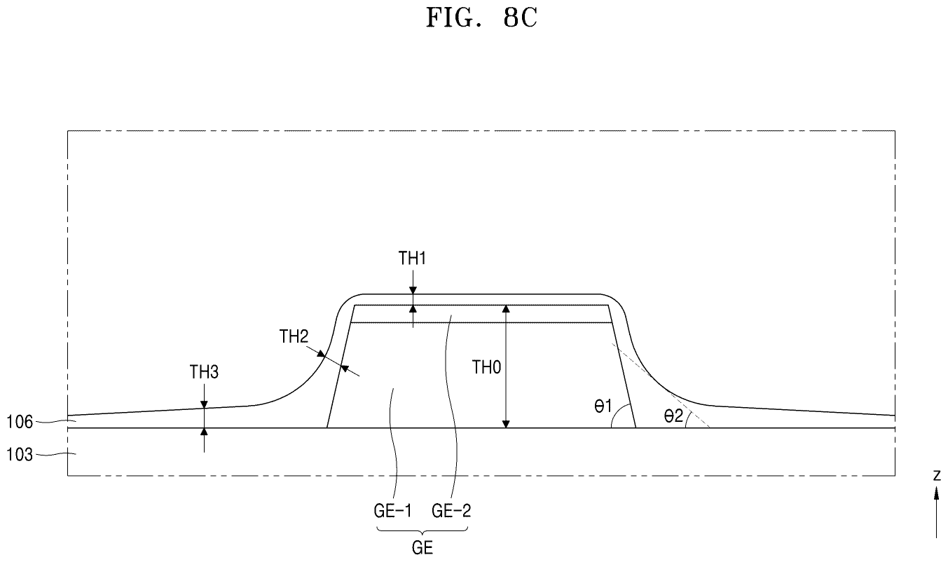

FIGS. 8A, 8B, and 8C are cross-sectional views illustrating operations of a manufacturing process of a display apparatus, according to another embodiment. Particularly, FIGS. 8A, 8B, and 8C may be cross-sectional views illustrating operations in the manufacturing process of the embodiment illustrated in FIG. 7.

Referring to FIGS. 8A and 8B together, the organic layer 106′ may be formed on the first insulating layer 103 to cover the gate electrode GE. The relationship between the first initial thickness TH1′, the second initial thickness TH2′, and the third initial thickness TH3′ of the organic layer 106′ is substantially the same as that described above. A portion of the organic layer 106′ overlapping the side surface of the gate electrode GE may form a third angle θ3 with the upper surface of the first insulating layer 103. In an embodiment, the first θ1 may be substantially the same as the third angle θ3.

Referring to FIGS. 8B and 8C together, in such an embodiment, the organic layer 106′ flows and changes its shape over time, and as a result, the third insulating layer 106 is formed. The flow process and shape change process of the organic layer 106′ may be substantially similar to those described above with reference to FIGS. 5A to 5C.

In an embodiment, for example, due to the flow of the organic layer 106′, the thickness of a portion of the organic layer 106′ disposed on the upper surface of the gate electrode GE (or the first initial thickness TH1′) may decrease to the first thickness TH1. The second initial thickness TH2′ and the third initial thickness TH3′ may also change to the second thickness TH2 and the third thickness TH3, respectively, by the flow of the organic layer 106′. Referring to FIGS. 8B and 8C, the second thickness TH2 is shown to be less than the second initial thickness TH2′, and the third thickness TH3 is shown to be less than the third initial thickness TH3′. However, the disclosure is not necessarily limited thereto. In another embodiment, the second thickness TH2 may be greater than the second initial thickness TH2′, and the third thickness TH3 may be greater than the third initial thickness TH3′. Due to the flow of the organic layer 106′, the third angle θ3 may also change to the second angle θ2. In an embodiment, the second angle θ2 may be less than the third angle θ3. As described above, the flow of the organic layer 106′ and formation of the third insulating layer 106 thereafter may alleviate the inclination formed by the side surface of the gate electrode GE.

According to embodiments of the disclosure as described above, a display apparatus including an insulating layer disposed on a gate electrode and capable of mitigating an inclination formed by a side surface of the gate electrode is provided.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. 1. A display apparatus comprising:
a first insulating layer;
a first electrode disposed on the first insulating layer and including a lower surface in contact with an upper surface of the first insulating layer, an upper surface opposite to the lower surface, and a side surface connecting the upper surface to the lower surface;
a second insulating layer disposed on the first electrode, overlapping the upper surface and the side surface of the first electrode, and comprising an inorganic insulating material; and
a third insulating layer disposed on the second insulating layer,
wherein a first portion and a second portion of the upper surface of the second insulating layer face each other with a gap around a point where the upper surface of the first insulating layer and the side surface of the first electrode meet each other, and
a portion of the third insulating layer is disposed in the gap.

2. The display apparatus of claim 1, wherein
the third insulating layer comprises an insulating material including silicon, oxygen, and carbon, and
a ratio of a number of carbon atoms to a number of silicon atoms in the third insulating layer is about 0.6 or less.

3. The display apparatus of claim 2, wherein the ratio of the number of carbon atoms to the number of silicon atoms of the third insulating layer is in a range of about 0.1 to about 0.6.

4. The display apparatus of claim 2, wherein a ratio of a number of oxygen atoms to the number of silicon atoms of the third insulating layer is in a range of about 1.5 to about 2.5.

5. The display apparatus of claim 1, wherein a thickness of a portion of the third insulating layer overlapping the upper surface of the first electrode is less than a thickness of a portion of the second insulating layer overlapping the upper surface of the first electrode.

6. The display apparatus of claim 1, wherein
a thickness of a portion of the third insulating layer overlapping the upper surface of the first electrode is less than a thickness of a portion of the third insulating layer overlapping the side surface of the first electrode.

7. The display apparatus of claim 1, wherein a thickness of a portion of the third insulating layer overlapping the upper surface of the first electrode is equal to or less than 1000 angstroms.

8. The display apparatus of claim 1, wherein a thickness of the first electrode is in a range of about 3500 angstroms to about 6000 angstroms.

9. The display apparatus of claim 1, wherein a first inclination angle formed by the side surface of the first electrode with respect to the upper surface of the first insulating layer is greater than a second inclination angle formed by an upper surface of a portion of the third insulating layer overlapping the side surface of the first electrode and the upper surface of the first insulating layer.

10. The display apparatus of claim 9, wherein the second inclination angle is in a range of about 50 degrees to about 60 degrees.

11. A display apparatus comprising:
a first insulating layer;
a first electrode disposed on the first insulating layer and including a lower surface in contact with an upper surface of the first insulating layer, an upper surface opposite to the lower surface, and a side surface connecting the upper surface to the lower surface;
a second insulating layer disposed on the first electrode, overlapping the upper surface and the side surface of the first electrode, and comprising an organic insulating material; and
a third insulating layer disposed on the third insulating layer and comprising an inorganic insulating material,
wherein a first inclination angle of the side surface of the first electrode with respect to the upper surface of the first insulating layer is greater than a second inclination angle formed by an upper surface of a portion of the third insulating layer overlapping the side surface of the first electrode with respect to the upper surface of the first insulating layer, and
the third insulating layer is in direct contact with the upper surface and the side surface of the first electrode.

12. The display apparatus of claim 11, wherein
the third insulating layer comprises an insulating material including silicon, oxygen, and carbon, and
a ratio of a number of carbon atoms to a number of silicon atoms of the third insulating layer is about 0.6 or less.

13. The display apparatus of claim 12, wherein the ratio of the number of carbon atoms to the number of silicon atoms of the third insulating layer is in a range of about 0.1 to about 0.6.

14. The display apparatus of claim 12, wherein a ratio of a number of oxygen atoms to the number of silicon atoms of the third insulating layer is in a range of about 1.5 to about 2.5.

15. The display apparatus of claim 11, wherein a thickness of a portion of the third insulating layer overlapping the upper surface of the first electrode is less than a thickness of a portion of the second insulating layer overlapping the upper surface of the first electrode.

16. The display apparatus of claim 11, wherein a thickness of a portion of the third insulating layer overlapping the upper surface of the first electrode is less than a thickness of a portion of the third insulating layer overlapping the side surface of the first electrode.

17. The display apparatus of claim 11, wherein a thickness of a portion of the third insulating layer overlapping the upper surface of the first electrode is equal to or less than 1000 angstroms.

18. The display apparatus of claim 11, wherein a thickness of the first electrode is in a range of about 3500 angstroms to about 6000 angstroms.

19. The display apparatus of claim 11, wherein a maximum thickness of the third insulating layer is less than a thickness of the first electrode.

20. The display apparatus of claim 11, wherein the second inclination angle is in a range of about 50 degrees to about 60 degrees.
